(19) United States
(12) Patent Application Publication
(10) Pub. No.: US 2009/0260859 A1
(43) Pub. Date: Oct. 22, 2009

(54) FLEXIBLE PRINTED CIRCUIT BOARD

(75) Inventors: YU-CHANG PAI, Tu-Cheng (TW); SHOU-KUO HSU, Tu-Cheng (TW); CHIA-NAN PAI, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/132,067

(22) Filed: Jun. 3, 2008

(30) Foreign Application Priority Data
Apr. 22, 2008 (CN) 200810301256.0

(51) Int. Cl. H05K 1/02; H05K 3/10

(52) U.S. Cl. 174/254; 333/238; 29/846

(57) ABSTRACT

A flexible printed circuit board (FPCB) includes a signal layer comprising a differential pair, a ground layer comprising a grounded sheet made of conductive material, and a dielectric layer located between the signal layer and the ground layer. A void is located on the two opposite sides of the grounded sheet in the ground layer. The differential pair comprises two transmission lines and each transmission line is capable of transmitting a differential signal. The distances between the middle line of the grounded sheet and the middle line of each of the two transmission lines are equal.

### CROSS-REFERENCES TO RELATED APPLICATION

Relevant subject matter is disclosed in co-pending U.S. patent applications entitled “FLEXIBLE PRINTED CIRCUIT BOARD” respectively filed on Nov. 29, 2007 with application Ser. No. 11/946,859 and filed on Dec. 5, 2007 with application Ser. No. 11/951,290, and assigned to the same assignee as that of the present application.

### BACKGROUND

1. Field of the Invention

The present invention relates to a flexible printed circuit board (FPCB), and particularly to an FPCB for transmitting high speed signals.

2. Description of related art

FPCBs are light, soft, thin, small, ductile, flexible and support high wiring density. FPCBs can be three-dimensionally wired and shaped according to space limitations. Flexible circuits are typically useful for electronic packages where flexibility, weight control and the like are important.

Referring to FIG. 2, a conventional FPCB includes a signal layer and a ground layer 50 according to the prior art. A differential pair 51 consisting of two transmission lines 52 and 54 is arranged in the signal layer. The ground layer is formed vertically beneath the signal layer and etched in a grid array. The layout in the ground layer 50 vertically beneath the transmission line 52 is different from that beneath the transmission line 54, noise is easily generated, which prevents the FPCB transmitting high speed signals.

What is needed, therefore, is an FPCB which can transmit high speed signals.

### SUMMARY

An embodiment of a flexible printed circuit board (FPCB) includes a signal layer comprising a differential pair, a ground layer comprising a grounded sheet made of conductive material, and a dielectric layer located between the signal layer and the ground layer. A void is located on the two opposite sides of the grounded sheet in the ground layer. The differential pair comprises two transmission lines and each transmission line is capable of transmitting a differential signal. The distances between the middle line of the grounded sheet and the middle line of each of the two transmission lines are equal.

Other advantages and novel features will become more apparent from the following detailed description when taken in conjunction with the accompanying drawings, in which:

### BRIEF DESCRIPTION OF THE DRAWINGS

FIG. 1 is a cross-sectional view of an FPCB according to an embodiment of the present invention; and

FIG. 2 is a schematic diagram of a conventional FPCB.

### DETAILED DESCRIPTION

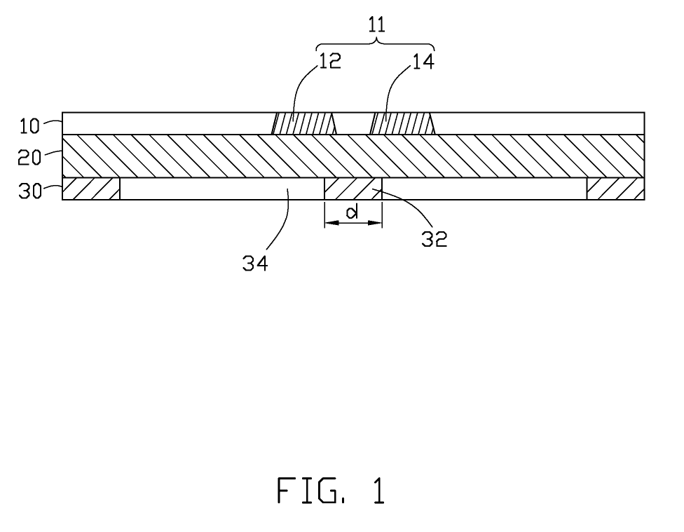

Referring to FIG. 1, an FPCB in accordance with an embodiment of the present invention includes a signal layer 10, a ground layer 30, and a dielectric layer 20 located between the signal layer 10 and the ground layer 30. A differential pair 11 comprising of two transmission lines 12, 14 is arranged in the signal layer 10, and is configured for transmitting a pair of differential signals. A grounded sheet 32 made of conductive material, such as copper, as a part of the ground layer 30 is arranged under the two transmission lines 12 and 14. The distances between the middle line of the grounded sheet 32 and the middle line of each of the two transmission lines 12 and 14 are equal. A void 34 is located on the two opposite sides of the grounded sheet 32 in the ground layer 30.

The width d of the grounded sheet 32 is obtained by simulating the FPCB of FIG. 1 using simulation software, simulating the type of the signal to be transmitted through the transmission lines 12 and 14 and the desired impedance of the transmission lines, and adjusting the width d of the grounded sheet 32, until desired characteristic impedances of the transmission lines 12 and 14 are achieved. The width d of the grounded sheet 32 is also affected by the following factors: the width of each transmission line 12, 14; a distance between the transmission line 12 and 14; widths of the void 34; and the height of the dielectric layer 20. For example, when the type of the differential signals is PCI-EXPRESS Gen I or SATA II or SAS, the desired characteristic impedances of the transmission lines 12 and 14 is 100Ω, the width of each of the transmission line 12 and 14 is 8 mils, and the distance between the transmission line 12 and 14 is 6 mils, the width of the grounded sheet 32 is 8 mils. When the type of the differential signals is IEEE 1394B, the desired characteristic impedances of the transmission lines 12 and 14 is 110Ω, the width of each of the transmission lines 12 and 14 is 7 mils, and the distance between the transmission lines 12 and 14 is 8 mils, the width of the grounded sheet 32 is 9 mils. When the type of the differential signals is PCI-EXPRESS Gen II, the desired characteristic impedances of the transmission lines 12 and 14 is 85Ω, the width of each of the transmission lines 12 and 14 is 10 mils, and the distance between the transmission lines 12 and 14 is 6 mils, the width of the grounded sheet 32 is 10 mils.

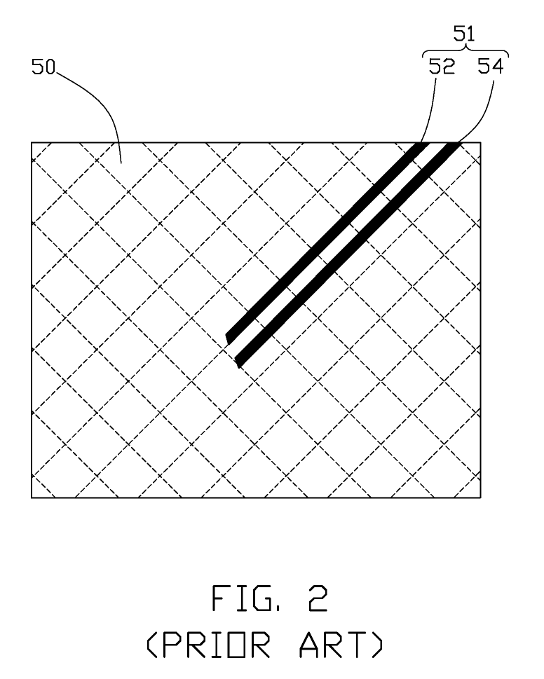

The layout of ground layer 30 beneath the transmission lines 12 and 14 are the same, and the noise caused by the grid array construction of the ground layer in FIG. 2 is reduced, and the impedance of the transmission line is matched, so the FPCB of the embodiment of the present invention can transmit high speed signals.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A flexible printed circuit board (FPCB), comprising:
a signal layer comprising a differential pair, the differential pair comprising of two transmission lines, each transmission line is capable of transmitting a differential signal;
a ground layer comprising a grounded sheet made of conductive material, a void located on the two opposite sides of the grounded sheet in the ground layer, wherein the distances between the middle line of the grounded sheet and the middle line of each of the two transmission lines are equal; and
a dielectric layer located between the signal layer and the ground layer.

2. The FPCB as claimed in claim 1, wherein each of the transmission lines has an impedance of 100Ω, the width of each of the transmission lines is 8 mils, and the distance between the transmission lines is 6 mils, and the width of the grounded sheet is 8 mils.

3. The FPCB as claimed in claim 1, wherein each of the transmission lines has an impedance of 110Ω, the width of each of the transmission lines is 7 mils, and the distance between the transmission lines is 8 mils, the width of the grounded sheet is 9 mils.

4. The FPCB as claimed in claim 1, wherein each of the transmission lines has an impedance of 85Ω, the width of each of the transmission lines is 10 mils, and the distance between the transmission lines is 6 mils, the width of the grounded sheet is 10 mils.

5. The FPCB as claimed in claim 1, wherein the grounded sheet is made of copper.

6. The FPCB as claimed in claim 1, wherein the grounded sheet has the same length as the transmission lines.

7. A method for making a flexible printed circuit board (FPCB), comprising:
providing a signal layer comprising a differential pair comprising of two transmission lines;
providing a dielectric layer beneath the signal layer;
providing a ground layer beneath the dielectric layer;
applying a grounded sheet made of conductive material in the ground layer, wherein the distances between the middle line of the grounded sheet and the middle of each of the two transmission lines are equal; and
removing material of the ground layer on both sides of the grounded sheet.

8. The method as claimed in claim 7, wherein each of the transmission lines has an impedance of 100Ω, the width of each of the transmission lines is 8 mils, and the distance between the transmission lines is 6 mils, and the width of the grounded sheet is 8 mils.

9. The method as claimed in claim 7, wherein each of the transmission lines has an impedance of 110Ω, the width of each of the transmission lines is 7 mils, and the distance between the transmission lines is 8 mils, the width of the grounded sheet is 9 mils.

10. The method as claimed in claim 7, wherein each of the transmission lines has an impedance of 85Ω, the width of each of the transmission lines is 10 mils, and the distance between the transmission lines is 6 mils, the width of the grounded sheet is 10 mils.

11. The method as claimed in claim 7, wherein the grounded sheet is made of copper.

12. The method as claimed in claim 7, wherein the grounded sheet has the same length as the transmission lines.
